(19) United States
(12) Patent Application Publication
(10) Pub. No.: US 2025/0351234 A1
(43) Pub. Date: Nov. 13, 2025

(54) SUBSTRATE HEAT TREATMENT DEVICE

(71) Applicant: Samsung Display Co., LTD., Yongin-si (KR)

(72) Inventors: Eun A PARK, Yongin-si (KR); Geon Ho YOON, Yongin-si (KR)

(21) Appl. No.: 19/040,602

(22) Filed: Jan. 29, 2025

(30) Foreign Application Priority Data
May 10, 2024 (KR) 10-2024-0062066

(51) Int. Cl. H05B 3/22; H01L 21/67

(52) U.S. Cl. CPC H05B 3/22; H01L 21/67109

(57) ABSTRACT

A substrate heat treatment device includes a heat treatment chamber having a heat treatment space, a gas injection unit located inside the heat treatment chamber and having a gas outlet configured to inject gas into the heat treatment chamber, and a diffusion guide positioned adjacent to the gas injection unit within the heat treatment chamber and extending along a first horizontal direction intersecting a discharge direction of the gas emitted through the gas outlet, wherein an inner surface of the diffusion guide facing the gas outlet includes a concave surface formed concavely along a second horizontal direction intersecting the first horizontal direction.

This application claims priority from Korean Patent Application No. 10-2024-0062066 filed on May 10, 2024, and all the benefits accruing therefrom under 35 U.S.C. § 119, the content of which in its entirety is herein incorporated by reference.

### BACKGROUND

### 1. Field

The present invention relates to a substrate heat treatment device, and more particularly to a substrate heat treatment device which provides a uniform gas flow velocity.

### 2. Description of the Related Art

As the information society advances, the demand for display devices to display images is increasing in various forms. For example, display devices are configured in various electronic devices such as smartphones, digital cameras, laptop computers, navigation systems, and smart televisions (TVs).

Several types of display devices such as liquid crystal displays (LCDs) and organic light-emitting displays are being used. Among these, organic light-emitting displays display images using organic light emitting elements that generate light through the recombination of electrons and holes. Organic light emitting displays include a plurality of transistors that provide driving current to the organic light emitting elements.

Particularly, display panels such as organic light emitting display panels are trending toward miniaturization and thinning.

In addition to these display devices, substrates used in the manufacturing of semiconductors and solar cells undergo various heat treatment processes for the formation of inorganic, organic, and/or semiconductor elements.

Specifically, substrates used in the manufacture of flat panel displays, semiconductors, and solar cells undergo heat treatment processes within a substrate heat treatment device to crystallize or change the phase of films deposited on the substrates through heat treatment.

In the heat treatment device, substrates to be heat-treated may be positioned apart from the upper side of a heater, allowing the substrates to be uniformly heated by the heater. Due to this heat treatment, it may be necessary to maintain a low concentration of oxygen and water vapor within the heat treatment device. Lowering and maintaining the concentration of oxygen and moisture is essential to ensure the quality and yield of the substrates, and to achieve this, gas can be supplied into the heat treatment device.

However, when injected toward the substrates within the substrate heat treatment device, the gas may be sprayed directly in a rectilinear direction towards the substrates. This direct injection and the resulting airflow deviations in the area of the injection can cause stains on the substrates. In other words, direct gas injection toward the substrates and the resulting non-uniform gas flow velocity can cause stains on the substrates, necessitating improvements in the uniformity of the gas flow velocity.

### SUMMARY

Aspects of the invention provide a substrate heat treatment device that can offer uniform gas flow velocity by guiding a diffusion guide to prevent gas from being sprayed directly in a rectilinear direction toward a substrate.

However, aspects of the invention are not restricted to those set forth herein. The above and other aspects of the invention will become more apparent to one of ordinary skill in the art to which the invention pertains by referencing the detailed description of the invention given below.

According to an embodiment, there is provided a substrate heat treatment device including a heat treatment chamber having a heat treatment space, a gas injection unit located inside the heat treatment chamber and having a gas outlet configured to inject gas into the heat treatment chamber and a diffusion guide positioned adjacent to the gas injection unit within the heat treatment chamber and extending along a first horizontal direction intersecting a discharge direction of the gas emitted through the gas outlet, wherein an inner surface of the diffusion guide facing the gas outlet includes a concave surface formed concavely along a second horizontal direction intersecting the first horizontal direction.

In an embodiment, the diffusion guide may include a central line, a first wing located on one side of the central line in the second horizontal direction, and a second wing located on the other side of the central line in the second horizontal direction.

In an embodiment, the central line may overlap with the gas outlet.

In an embodiment, the first wing and the second wing may have symmetrical shapes with respect to the central line.

In an embodiment, each of the first wing and the second wing may approach closer to the gas injection unit than from the central line.

In an embodiment, each of the first wing and the second wing may be spaced apart from the gas injection unit.

In an embodiment, a space disposed between the first wing and the gas injection unit and a space disposed between the second wing and the gas injection unit may constitute a gas discharge space.

In an embodiment, the gas discharge space may have a slit shape extending in the first horizontal direction.

In an embodiment, angles formed by the first wing and the second wing with respect to a vertical direction directed perpendicular to the first horizontal direction and the second horizontal direction may be each between about 70 degrees and about 89 degrees.

In an embodiment, the gas injection unit may include a plurality of gas outlets arranged along a longitudinal direction of the gas injection unit, wherein the plurality of gas outlets may be spaced apart from one another at intervals of about 60 mm to about 75 mm.

In an embodiment, the substrate heat treatment may further include a heating unit located inside the heat treatment chamber and including a gas discharge hole connected to the gas outlet, wherein the gas injection unit may be coupled to the heating unit at a position where the gas outlet and the gas discharge hole are connected.

In an embodiment, the heating unit may be arranged continuously along the first horizontal direction, where the heating unit may include a heating plate including the gas discharge hole, and a heat pipe coupled to the heating plate, wherein the gas injection unit may include a gas supply pipe coupled to the heating plate while being spaced apart from the heat pipe and overlapping with the gas discharge hole.

In an embodiment, the diffusion guide may be spaced apart from the heating plate with the gas discharge space disposed therebetween.

In an embodiment, the diffusion guide may include a block shape arranged continuously along a longitudinal direction of the heating plate.

In an embodiment, the substrate heat treatment device may further include a substrate support located inside the heat treatment chamber and positioned to face the heating unit to support a substrate to be heat-treated.

In an embodiment, the substrate heat treatment device may further include a gas supply unit connected to the gas injection unit to supply gas to the gas injection unit, and a gas discharge unit for discharging the gas supplied into the heat treatment chamber to the outside of the heat treatment chamber.

According to another embodiment, there is provided a substrate heat treatment device including a heat treatment chamber having a heat treatment space, a gas injection unit located inside the heat treatment chamber and including a gas outlet configured to inject gas into the heat treatment chamber and a diffusion plate positioned adjacent to the gas injection unit within the heat treatment chamber and located in a first horizontal direction intersecting a discharge direction of the gas emitted through the gas outlet, wherein the diffusion plate includes a guide surface configured to move the gas in a direction that is opposite to the discharge direction.

In an embodiment, the diffusion plate may include a bent portion located in a central region and a pair of inclined portions extending symmetrically in both directions from the bent portion, wherein the pair of inclined portions may each include the guide surface.

In an embodiment, the pair of inclined portions may each have an inclination angle range of about 70 degrees to about 89 degrees with respect to a straight line directed in the discharge direction.

In an embodiment, the gas injection unit may include a plurality of gas outlets arranged along a longitudinal direction of the gas injection unit, wherein the plurality of gas outlets may be spaced apart from one another at intervals of about 60 mm to about 75 mm.

It should be noted that the effects of the invention are not limited to those described above, and other effects of the invention will be apparent from the following description.

### BRIEF DESCRIPTION OF THE DRAWINGS

The above and other aspects and features of the invention will become more apparent by describing in detail exemplary embodiments thereof with reference to the attached drawings, in which:

FIG. 1 is a perspective view of a substrate heat treatment device, according to an embodiment;

FIG. 2 is a front view of the substrate heat treatment device, according to an embodiment;

FIG. 3 is a sectional side view of the substrate heat treatment device, according to an embodiment;

FIG. 4 is a perspective view of a heating module for the substrate heat treatment device of FIG. 1, according to an embodiment;

FIG. 5 is a top plan view of the heating module of FIG. 4, according to an embodiment;

FIG. 6 is a diagram illustrating a gas supply pipe and a diffusion guide for the heating module of FIG. 4 with a pitch of about 68 mm between gas outlets, according to an embodiment;

FIG. 7 is a bottom perspective view of the heating module of FIG. 4, according to an embodiment;

FIG. 8 is a rear bottom view of the heating module of FIG. 4, according to an embodiment;

FIG. 9 is an exploded bottom perspective view of the heating module and diffusion guides of FIG. 7, according to an embodiment;

FIG. 10 is a partially enlarged cross-sectional view illustrating the combined state of a heating plate and a diffusion guide of FIG. 7, according to an embodiment;

FIG. 11 is a perspective view of a diffusion guide of FIG. 9, according to an embodiment;

FIG. 12 is a partially enlarged view illustrating the arrangement state of a heating module, a diffusion guide, and a substrate according of FIG. 2, according to an embodiment;

FIG. 13 is a partially enlarged cross-sectional view illustrating parts of the heating module, diffusion guide, and substrate FIG. 12, according to an embodiment;

FIG. 14 is an enlarged cross-sectional view illustrating the heating module and diffusion guide of FIG. 13, according to an embodiment;

FIG. 15 is a partially enlarged cross-sectional view illustrating gas flows toward the substrate through the heating module and diffusion guide of FIG. 14, according to an embodiment;

FIG. 16 is a photograph showing temperature simulation results for the heating plate bottom surface with a diffusion guide arranged at an angle of about 75 degrees of FIG. 15, according to an embodiment;

FIG. 17 is a partially enlarged cross-sectional view illustrating the state of a diffusion guide arranged at an angle of about 80 degrees on the bottom surface of a heating plate of FIG. 10, according to an embodiment;

FIG. 18 is a photograph showing the temperature simulation results for the heating plate bottom surface with the diffusion guide arranged at an angle of about 80 degrees of FIG. 17, according to an embodiment;

FIG. 19 is a partially enlarged cross-sectional view illustrating the state of a diffusion guide arranged at an angle of about 85 degrees on the bottom surface of the heating plate of FIG. 10, according to an embodiment;

FIG. 20 is a photograph showing the temperature simulation results for the heating plate bottom surface with the diffusion guide arranged at an angle of about 85 degrees of FIG. 19, according to an embodiment;

FIG. 21 is a view showing the state of a diffusion guide arranged at an angle of about 90 degrees on the bottom surface of the heating plate of FIG. 10, according to an embodiment;

FIG. 22 is a photograph showing the temperature simulation results for the heating plate bottom surface with the diffusion guide arranged at an angle of about 90 degrees of FIG. 21, according to an embodiment;

FIG. 23 is a cross-sectional view of a gas supply pipe with a pitch of about 136 mm between gas outlets of FIG. 4, according to an embodiment; and

FIG. 24 is a graph comparing the flow uniformity of the gas supply pipe with a pitch of about 68 mm in FIG. 6 and the gas supply pipe with a pitch of about 136 mm in FIG. 23, according to an embodiment.

### DETAILED DESCRIPTION

Embodiments of the invention will now be described more fully hereinafter with reference to the accompanying drawings, in which embodiments of the invention are shown. The invention may, however, be embodied in different forms and should not be construed as limited to the embodiments set forth herein. Rather, these embodiments are provided so that this disclosure will be thorough and complete, and will filly convey the scope of the invention to those skilled in the art. The same reference numbers indicate the same components throughout the specification. In the attached drawing figures, the thickness of layers and regions is exaggerated for clarity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will also be understood that when a layer is referred to as being “on” another layer or substrate, it can be directly on the other layer or substrate, or intervening layers may also be present. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” “At least one of A and B” means “A and/or B.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. A region illustrated or described as flat may, typically, have rough and/or nonlinear features, for example. Moreover, sharp angles that are illustrated may be rounded. Thus, the regions illustrated in the drawing figures are schematic in nature and their shapes are not intended to illustrate the precise shape of a region and are not intended to limit the scope of the claims.

Embodiments of the invention will be described with reference to the attached drawings.

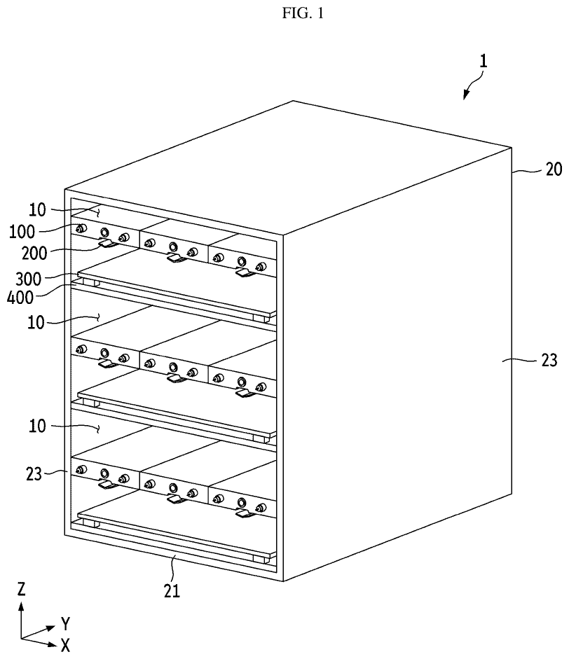

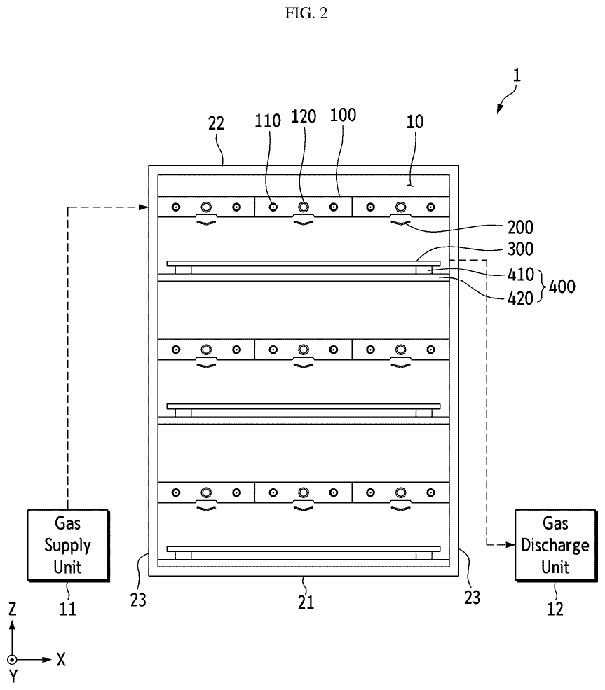

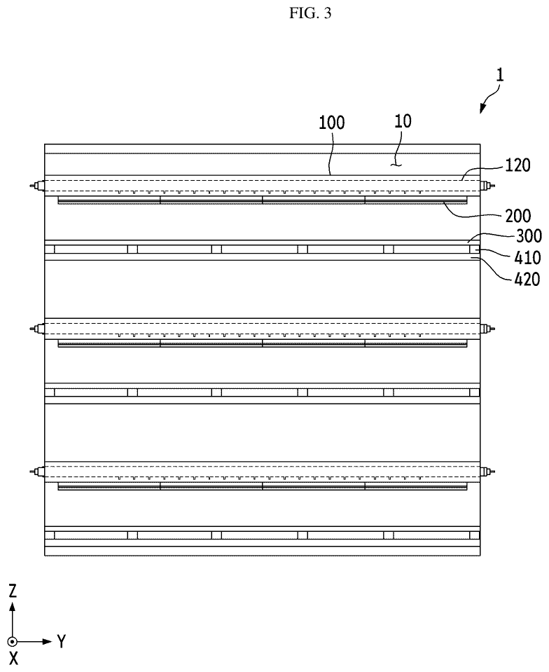

FIG. 1 is a perspective view of a substrate heat treatment device, according to an embodiment, FIG. 2 is a front view of the substrate heat treatment device of FIG. 1, according to an embodiment, and FIG. 3 is a cross-sectional side view of the substrate heat treatment device of FIG. 1, according to an embodiment.

In an embodiment and referring to FIGS. 1 and 2, a substrate heat treatment device 1 may include a heat treatment chamber 20, which includes a heat treatment space 10 for one or more substrates 300, substrate supports 400, which supports the substrates 300 within the heat treatment chamber 20, a heating module, which includes a plurality of heating units 100 for heating the substrates 300 seated on the substrate supports 400, and one or more diffusion guides 200, which are positioned below the heating units 100.

In an embodiment, the heat treatment chamber 20 includes a receiving space that is hollow inside, and this receiving space may serve as one or more heat treatment spaces 10 capable of receiving and heat-treating the substrates 300.

A single heat treatment space 10 or multiple heat treatment spaces 10 obtained by dividing the receiving space may be provided. For example, when a single heat treatment space 10 is provided, the heat treatment space 10 may receive and heat-treat a single substrate 300, but the invention is not limited thereto.

In another embodiment, in another example, as illustrated in FIG. 1, the single receiving space formed by the heat treatment chamber 20 may be partitioned with three substrate supports 400 and may thereby be divided into three heat treatment spaces 10, but the invention is not limited thereto. That is, more than three heat treatment spaces 10 may be formed depending on the number of substrate supports 400 that are installed. The heat treatment spaces 10 in FIG. 1 may be either independent spaces that do not communicate with one another or they may be spaces that communicate with one another. When there are multiple heat treatment spaces 10, multiple substrates 300 may be introduced and heat-treated at once, but the invention is not limited thereto. In still another embodiment, the substrates 300 may be received and heat-treated one at a time.

In an embodiment, the heat treatment chamber 20 may have a cubic shape externally and may include the heat treatment spaces 10. As illustrated in FIG. 1, the heat treatment chamber 20 may have a rectangular cubic shape, but the invention is not limited thereto. In another embodiment, the heat treatment chamber 20 may have a square cubic shape, a circular or elliptical shape, or a long tube shape.

For example, if the heat treatment chamber 20 has a cubic shape, the heat treatment chamber 20 may include a chamber bottom surface 21, which is positioned on the installation surface where the substrate heat treatment device 1 is installed, a chamber top surface 22, which is disposed opposite to the chamber bottom surface 21, and three chamber side surfaces 23, which are positioned circumferentially between the chamber bottom surface 21 and the chamber top surface 22, except for a front opening of the heat treatment chamber 20.

In an embodiment, the heat treatment chamber 20 may have a cubic shape with a front opening through which the substrates 300 may be introduced into the heat treatment space 10. As depicted in FIG. 1, an opening may be located at the front of the heat treatment chamber 20, and the heat treatment chamber 20 may be provided as a sealed chamber capable of sealing its internal space by further including a door to open or close the front opening. However, the invention is not limited to this. That is, the heat treatment chamber 20 may take various other forms as long as it can form an open or sealed space for heat treatment inside.

In an embodiment and referring to FIG. 2, the substrate supports 400 may support the substrates 300 introduced into the heat treatment spaces 10 within the internal space of the heat treatment chamber 20, and the substrates 300, which are targets to be heat-treated, may be seated on the substrate supports 400.

In an embodiment, the substrate supports 400 may be integrally provided with the chamber side surfaces 23 of the heat treatment chamber 20, they may be fixedly coupled to the heat treatment chamber 20, or they may be detachably coupled to allow the substrate supports 400 to be introduced into and withdrawn from the heat treatment chamber 20. When the substrate supports 400 are detachably coupled, sliding means may be provided on the inner surfaces of the substrate supports 400 and the chamber side surfaces 23. For example, the sliding means may include sliding ribs and rib guides into which the sliding ribs are inserted, allowing the substrate supports 400 to slide along the rib guides to be introduced and withdrawn, but the invention is not limited thereto. Additionally, when the substrate supports 400 are detachably coupled, the substrate supports 400 may serve as partitioning sections that partition the internal space of the heat treatment chamber 20.

In an embodiment, the substrate supports 400 may include support plates 420, which are positioned apart from the substrates 300, and support pins 410, which protrude from the support plates 420 to support the bottom surfaces of the substrates 300. As illustrated in FIG. 2, the support pins 410 may be provided in pairs on both side edge regions of the support plates 420 or may be provided in multiple numbers along the circumferential direction of the support plates 420. However, the invention is not limited to these.

In an embodiment and referring to FIG. 2, the substrate heat treatment device 1 may further include a gas supply unit 11, which supplies gas into the interior of the heat treatment chamber 20, and a gas discharge unit 12, which discharges gas from the interior of the heat treatment chamber 20.

In an embodiment, the gas supply unit 11 may supply gas to the interior of the heat treatment chamber 20 through gas supply pipes 120, and may include a gas supply pump connected to the gas supply pipes 120 for supplying gas, but the invention is not limited thereto. The gas supply unit 11 may supply gas to each of a plurality of heating units 100, or a plurality of sub-gas supply units may branch from a single gas supply unit 11 and supply gas to the heating units 100 together. However, the invention is not limited to these.

In an embodiment, the gas discharge unit 12 may discharge gas supplied into the heat treatment chamber 20 through the gas supply pipes 120 to the outside of the heat treatment chamber 20 and may include a gas discharge pump connected to the internal space of the heat treatment chamber 20 to discharge the gas, but the invention is not limited thereto. The gas discharge unit 12 may discharge the gas from each of the spaces defined by the substrate supports 400, or a plurality of sub-gas discharge units may branch from a single gas discharge unit 12 and discharge the gas from the heat treatment chamber 20 at once. However, the invention is not limited to these.

In an embodiment and referring to FIGS. 2 and 3, the heating module may include a plurality of heating units 100 that generate heat. Specifically, the heating module may be an assembly formed by the heating units 100, which are block-shaped and arranged continuously along an X-axis direction. That is, the heating module may be an assembly of multiple heating units 100.

In an embodiment, the heating units 100 may be positioned apart from the upper parts of the substrates 300 that are seated on the substrate supports 400, and may heat the substrates 300. Specifically, the heating units 100 may generate and provide heat from positions apart from the substrates 300 in a Z-axis direction, which is the upward direction of the substrates 300.

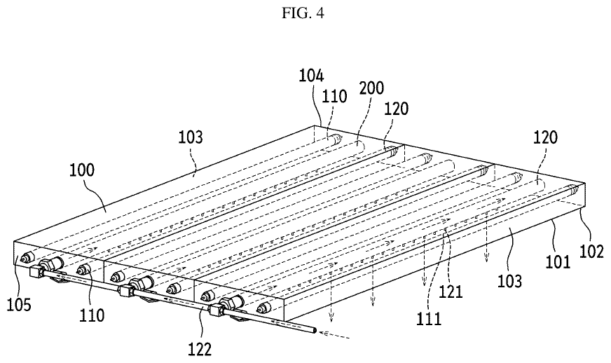

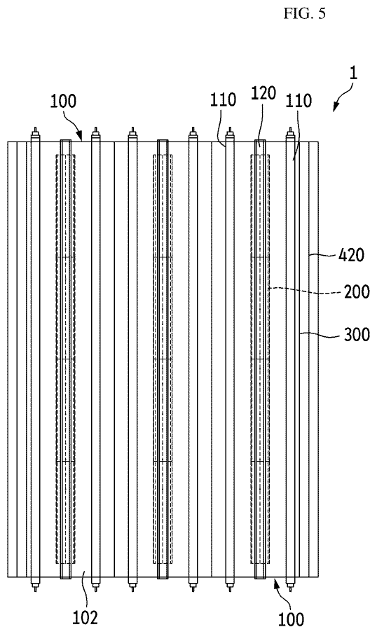

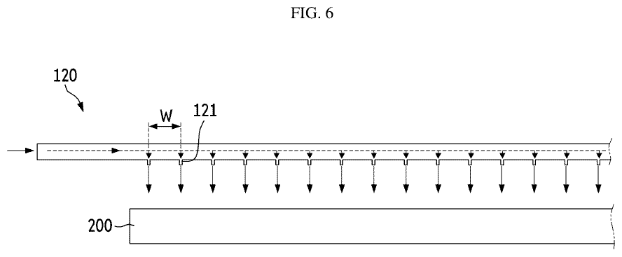

FIG. 4 is a perspective view of a heating module of FIG. 1, according to an embodiment, FIG. 5 is a top plan view of the heating module of FIG. 4, according to an embodiment, and FIG. 6 is a diagram illustrating a gas supply pipe and a diffusion guide of FIG. 4 with a pitch of about 68 mm between gas outlets, according to an embodiment.

In an embodiment and referring to FIG. 4, a plurality of heating units 100 may be arranged along the X-axis direction above the substrates 300. In another embodiment, a single heating unit 100 having the same width as the heat treatment chamber 20 in the X-axis direction may be provided.

Specifically, a plurality of heating units 100 may be interconnected continuously by a fastening means to form an integral unit or they may be continuously arranged in contact without separate fastening means and then fixed to the heat treatment chamber 20. The heating units 100 may be arranged to be continuously connected while being in contact with one another in the X-axis direction or they may be arranged with intervals therebetween.

In an embodiment, each of the heating units 100 may include a heating plate (101, 102, 103, 104, and 105), heat pipes 110 embedded in the heating plate (101, 102, 103, 104, and 105), and gas supply pipes 120 positioned parallel to the heat pipes 110.

In an embodiment, the heating plate (101, 102, 103, 104, and 105) may include a receiving space that is hollow inside, and this receiving space may be a space capable of accommodating the heat pipes 110 and the gas supply pipes 120.

The heating plate (101, 102, 103, 104, and 105) may have a cubic shape with an internal space to accommodate the heat pipes 110 and gas supply pipes 120. The heating plate (101, 102, 103, 104, and 105) may have a cubic shape with a rectangular cross-section, but the invention is not limited thereto. In another embodiment, the heating plate (101, 102, 103, 104, and 105) may have a polyhedral shape with a triangular, square, pentagonal, or hexagonal cross-section, or may have a long tube shape.

In an embodiment, when the heating plate (101, 102, 103, 104, and 105) has a cubic shape with a rectangular cross-section, the heating plate (101, 102, 103, 104, and 105) may include a heating plate bottom surface 101, which faces a substrate 300, a heating plate top surface 102, which is disposed opposite to the heating plate bottom surface 101, a heating plate front surface 104, which is located on the front opening side of the heat treatment chamber 20, a heating plate rear surface 105, which is disposed opposite to the heating plate front surface 104, and a pair of heating plate side surfaces 103.

In an embodiment, the heating plate (101, 102, 103, 104, and 105) may be formed of a metal material such as aluminum or stainless steel, but the invention is not limited thereto. When the heat pipes 110 generate heat, this heat is transferred to the front surface 104 and rear surface 105 of the heating plate (101, 102, 103, 104, and 105) in contact with the heat pipes 110. Then, the heated heating plate (101, 102, 103, 104, and 105) may provide heat to the substrate 300 located in the corresponding heat treatment space 10. Thus, the heating plate (101, 102, 103, 104, and 105) may be formed of various materials. Here, the heating plate (101, 102, 103, 104, and 105) may be heated by the heat pipes 110 to heat-treat the substrate 300, but the invention is not limited thereto. The heat pipes 110 may also heat gas, which may then be used to heat-treat the substrate 300.

In an embodiment, the heating plate top surface 102 may face the chamber top surface 22 of the heat treatment chamber 20, and a plurality of gas discharge holes 111 may be formed in the heating plate bottom surface 101. The heating plate bottom surface 101 with the gas discharge holes 111 may face the diffusion guides 200.

In an embodiment, terminal portions of each of the heat pipes 110 and gas supply pipes 120 may be coupled to the heating plate front surface 104 and the heating plate rear surface 105. Here, the heat pipes 110 and the gas supply pipes 120 may be arranged in the Y-axis direction with intervals disposed therebetween to be disposed parallel to one another.

In an embodiment, a pair of heat pipes 110 may be provided with each gas supply pipe 120 to be positioned therebetween in a single heating unit 100, but the invention is not limited thereto. In another embodiment, a single heat pipe 110 or more than two heat pipes 110 may be provided in one heating unit 100.

In an embodiment, the heat pipes 110 may consist of various heaters, for example, sheath heaters, but the invention is not limited thereto. Here, the sheath heaters are metal pipes, called metal sheaths, densely filled and compressed with magnesia (MgO), and have heating wires and terminal pins connected and fixed at the center of the sheaths to enhance thermal conductivity and minimize the temperature difference between the heating wires and the metal sheaths. The sheath heaters have excellent thermal conductivity and efficiency due to the high-density compression of the insulator, preventing oxidation of the heating wires and extending their lifespan. The sheath heaters also have excellent corrosion resistance, acid resistance, and heat resistance when using ceramic coating, metallic cladding, Teflon tubing, or coating. The sheath heaters can emit infrared radiation upward and downward, and the substrates 300 can be uniformly heated by convection of heated air as well as infrared radiation heating.

When the heat pipes 110 are equipped with the sheath heaters, the heat pipes 110 can be electrically connected using heater cables (not illustrated) to achieve electrical connectivity. Heater cables for wiring (not illustrated) can also be used to connect multiple sheath heaters into a single integral structure.

In an embodiment and referring to FIGS. 5 and 6, each gas supply pipes 120, which is a gas injection part, may be positioned between a pair of heat pipes 110, but the invention is not limited thereto. In another embodiment, multiple gas supply pipes 120 may be positioned between a pair of heat pipes 110.

In an embodiment, the gas supply pipes 120 may supply gas into the heat treatment chamber 20 to lower and maintain the concentration of oxygen and moisture within the heat treatment chamber 20, which is a crucial process for maintaining the quality and yield of substrates. Specifically, the atmosphere for the heating process for the substrate 300 may require low concentrations of oxygen and water vapor. To achieve this, most of the gas may be replaced with nitrogen and pressurized. In the heating process for the substrate 300, nitrogen gas may be injected, but the invention is not limited thereto.

Each of the gas supply pipes 120 may include a plurality of gas outlets 121 arranged along the Y-axis direction on their surface facing the heating plate bottom surface 101 and the diffusion guides 200 located below the heating plate bottom surface 101. The gas outlets 121 may be holes penetrating the surfaces of the gas supply pipes 120.

In an embodiment, a plurality of gas outlets 121 may be arranged at regular intervals along the gas supply pipes 120, and a spacing W between the gas outlets 121 may be between about 60 mm to about 75 mm. Specifically, the pitch between the gas outlets 121 may be about 60 mm to about 75 mm, but the invention is not limited thereto. For example, when the spacing W between the gas outlets 121 is about 68 mm, 60 gas outlets 121 may be provided in one gas supply pipe 120, but the invention is not limited thereto. When the pitch or the spacing W between the gas outlets 121 is about 68 mm, the internal pressure of the gas supply pipes 120 can be reduced, and the uniformity of the gas discharge speed through the gas outlets 121 can be enhanced. Ultimately, the flow velocity of the gas discharged to the substrate 300 can be equalized.

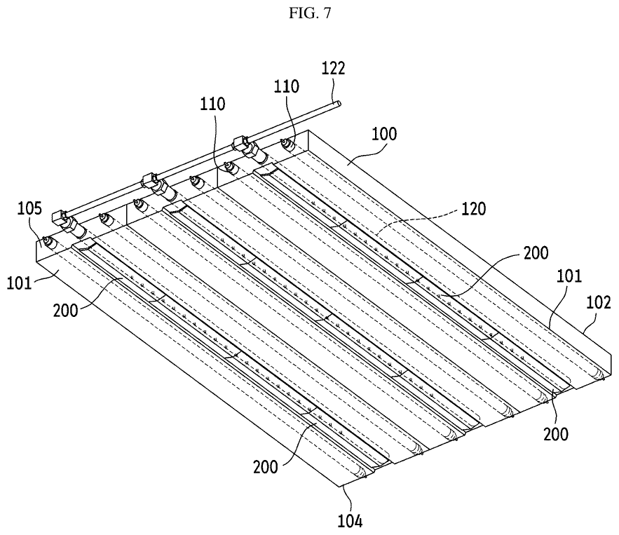

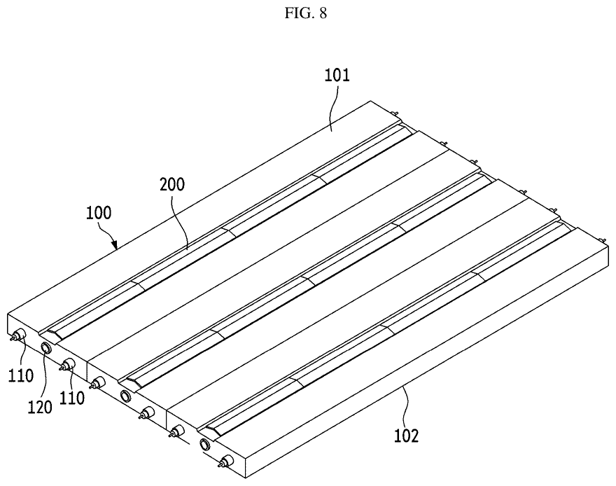

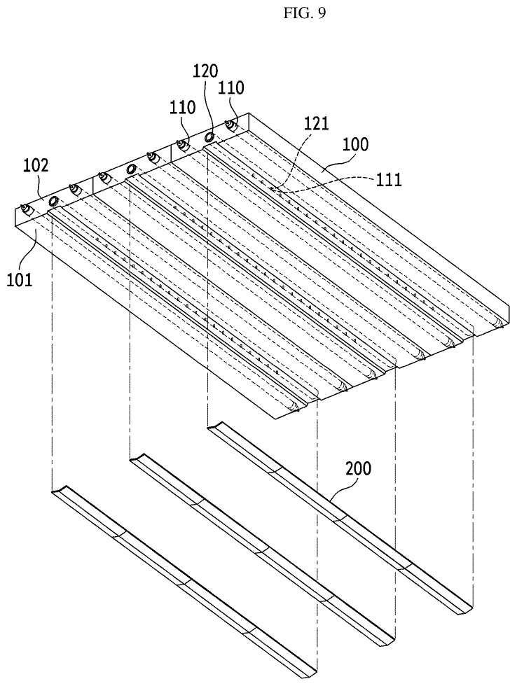

FIG. 7 is a bottom perspective view of the heating module of FIG. 4, according to an embodiment, FIG. 8 is a rear bottom view of the heating module of FIG. 4, according to an embodiment, and FIG. 9 is an exploded bottom perspective view of the heating module and diffusion guides of FIG. 7, according to an embodiment.

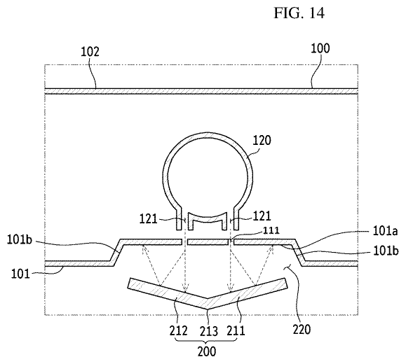

In an embodiment, the gas outlets 121 of each of the gas supply pipes 120 are arranged to face the heating plate bottom surface 101. The gas discharge holes 111 may be formed in the heating plate bottom surface 101 to correspond to and communicate with the gas outlets 121, as shown in FIG. 14.

In an embodiment, the gas supply pipes 120 are connected to a gas connection pipe 122, which is located on the heating plate rear surface 105, where the gas connection pipes 122 connect the gas supply unit 11 with the gas supply pipes 120.

In an embodiment, the gas discharge holes 111 of each of the gas supply pipes 120 are formed to penetrate the heating plate bottom surface 101 and may have the same shape, positions, and quantity as the gas outlets 121, but the invention is not limited thereto. The gas discharge holes 111 may ultimately discharge gas supplied from the gas outlets 121 of each of the gas supply pipes 120 into the internal space of the heat treatment chamber 20.

Thus, the gas from the gas supply unit 11 is supplied to the gas supply pipes 120 through the gas connection pipe 122. The gas flowing through the gas supply pipe 120 is discharged through the gas outlets 121, and the gas discharged through the gas outlets 121 is finally discharged into the internal space of the heat treatment chamber 20 through the gas discharge holes 111 of the heating plate bottom surface 101, which are in communication with the gas outlets 121.

In an embodiment and referring to FIGS. 8 and 9, the diffusion guides 200 may be spaced apart from the heating plate bottom surface 101 and arranged continuously along the gas discharge holes 111 of the heating plate bottom surface 101, i.e., along the Y-axis direction.

In an embodiment, a plurality of diffusion guides 200, also referred to as diffusion plates, may be provided and arranged along the Y-axis direction on the heating plate bottom surface 101, but the invention is not limited thereto. In another embodiment, a single diffusion guide 200 may be provided in the form of a long bar.

The diffusion guides 200 may be continuously interconnected by a fastening means to form an integral unit or they may be continuously arranged to be in contact without a separate fastening means and then fixed to the heating plate bottom surface 101. A plurality of diffusion guides 200 may be arranged to be continuously connected in contact with one another along the Y-axis direction or they may be arranged with intervals disposed therebetween. Additionally, the ends of each of the diffusion guide 200 may be aligned with the ends of each of the heating plate front surface 104 and/or the heating plate rear surface 105, or they may protrude beyond or be recessed from the ends of each of the heating plate front surface 104 and the heating plate rear surface 105.

In an embodiment, the diffusion guides 200 may be coupled to the heating plate bottom surface 101 at positions overlapping the gas supply pipes 120, while being spaced apart from the heating plate bottom surface 101. The diffusion guides 200 indirectly deflect gas so that the gas discharged from the gas outlets 121 of the gas supply pipes 120 and the gas discharge holes 111 of the heating plate bottom surface 101 is not directly sprayed onto the substrate 300.

The diffusion guides 200 may be formed of the same metal as the heating plate bottom surface 101, for example, aluminum or stainless steel, or may be formed of a plastic material that does not undergo thermal deformation.

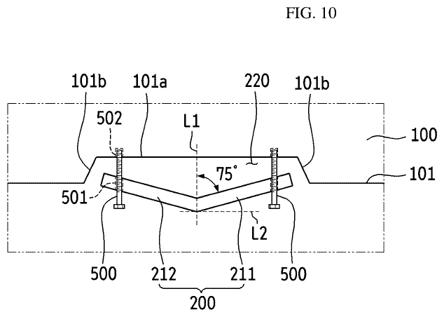

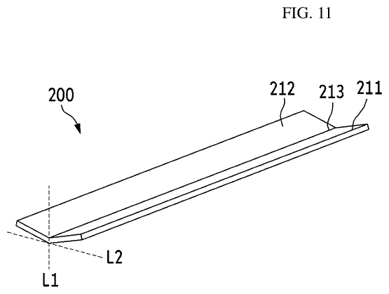

FIG. 10 is a partially enlarged cross-sectional view illustrating the combined state of a heating plate and a diffusion guide of FIG. 7, according to an embodiment, and FIG. 11 is a perspective view of a diffusion guide of FIG. 9, according to an embodiment.

In an embodiment and referring to FIG. 10, a diffusion guide 200 may be coupled to a heating plate bottom surface 101 by a coupling means (500, 501, and 502).

In an embodiment, the coupling means (500, 501, and 502) may include a first fastening hole 501, which is formed in the diffusion guide 200, a second fastening hole 502, which is formed in the heating plate bottom surface 101, and fastening members, such as fastening bolts 500, which are inserted into the first and second fastening holes 501 and 502, respectively, to secure the diffusion guide 200 to the heating plate bottom surface 101. However, the invention is not limited to this. In another embodiment, the coupling means (500, 501, and 502) may include coupling projections and coupling grooves to secure the diffusion guide 200 to the heating plate bottom surface 101, or the diffusion guide 200 may be bonded to the heating plate bottom surface 101 using a thermosetting adhesive.

In an embodiment and referring to FIGS. 10 and 11, the diffusion guide 200 may include a bent portion 213 with a concave surface, and first and second wings 211 and 212, respectively, which are symmetrically arranged on both sides of the bent portion 213 and which serve as guide surfaces or inclined portions that guide gas in the opposite direction of the discharge direction of the gas.

The diffusion guide 200 may be installed in an installation unit (101a and 101b) formed as recesses in the heating plate bottom surface 101. Here, the installation unit (101a and 101b) may include a first installation surface 101a, which faces the bent portion 213, and a pair of second installation surfaces 101b, which faces the ends of the wings 211 and 212.

The diffusion guide 200 may have a V-shape in a cross-sectional view, but the invention is not limited thereto. In another embodiment, the diffusion guide 200 may have various other concave shapes, such as a U-shape or W-shape.

In an embodiment, in the diffusion guide 200, the bent portion 213 may be positioned in the gas discharge direction, which is opposite to the Z-axis direction, and the wings 211 and 212 may be arranged in the X-axis direction, which is perpendicular to the gas discharge direction. The spacing between the diffusion guide 200 and the heating plate bottom surface 101 may correspond to a gas discharge space 220 of FIG. 14. For example, referring to FIG. 14, the vertical width of the gas discharge space 220 disposed along a first reference line L1 may be about 1 mm to about 3 mm, preferably about 2.5 mm, and at about 2.5 mm, the uniformity of the gas flow velocity may be excellent.

In the diffusion guide 200, based on the first reference line L1 and a second reference line L2 intersecting the first reference line L1, the first wing 211 may have an inclination angle of about 70 degrees to about 89 degrees from the first reference line L1. If the second wing 212 is symmetrical to the first wing 211, the inclination angle of the second wing 212 may also be about 70 degrees to about 89 degrees. For example, if the inclination angle of the diffusion guide 200 is about 75 degrees as illustrated in FIG. 10, the airflow of the gas flowing through a gas supply pipe 120 may be changed, and the gas discharge space 220 may be formed in the internal space between the heating plate bottom surface 101 and the diffusion guide 200, which can improve the uniformity of the gas flow velocity through the gas discharge space 220. That is, when the inclination angle of the diffusion guide 200 is about 75 degrees, the gas discharge space 220 may act as a common chamber, resulting in a uniform gas flow velocity through the diffusion guide 200.

In the diffusion guide 200, the inner surfaces of the wings 211 and 212 serve as guide surfaces that guide the gas discharged through the gas discharge holes 111 to not proceed directly toward a substrate 300. Specifically, the gas discharged through the gas discharge holes 111 is guided toward the heating plate bottom surface 101 by the guide surfaces, causing the gas to hit the installation unit (101a and 101b) of the heating plate bottom surface 101 before heading toward the substrate 300.

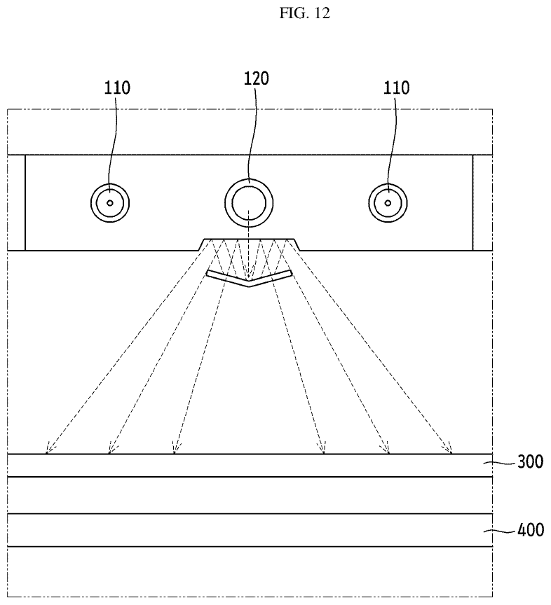

It will hereinafter be described how to guide gas to a substrate using a diffusion guide with reference to FIGS. 12 through 16, according to an embodiment.

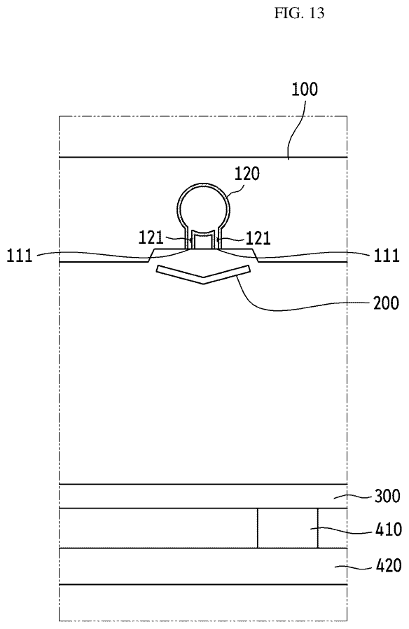

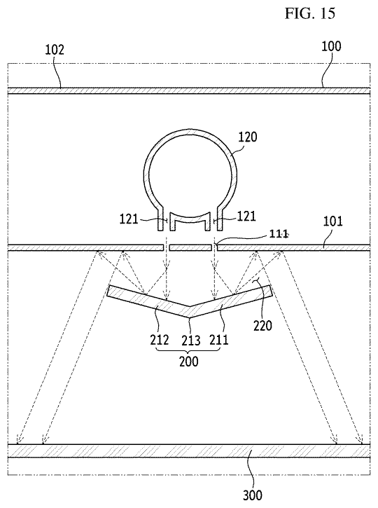

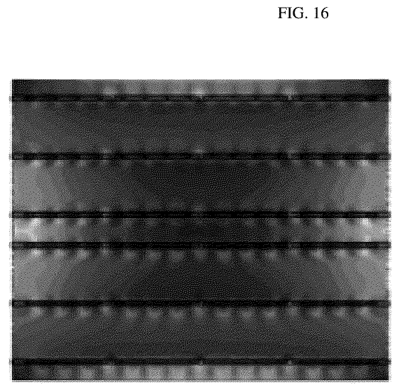

FIG. 12 is a partially enlarged view illustrating the arrangement state of a heating module, a diffusion guide, and a substrate of FIG. 2, according to an embodiment, FIG. 13 is a partially enlarged cross-sectional view illustrating parts of the heating module, diffusion guide, and substrate according of FIG. 12, according to an embodiment, FIG. 14 is an enlarged cross-sectional view illustrating the heating module and diffusion guide of FIG. 13, according to an embodiment, FIG. 15 is a partially enlarged cross-sectional view illustrating gas flows toward the substrate through the heating module and diffusion guide of FIG. 14, according to an embodiment, and FIG. 16 is a photograph showing temperature simulation results for the heating plate bottom surface with a diffusion guide arranged at an angle of about 75 degrees according to the embodiment of FIG. 15.

In an embodiment and referring to FIG. 12, when gas is supplied to a gas supply pipe 120, the gas starts to be discharged through gas outlets 121 of the gas supply pipe 120. Then, referring to FIG. 13, the gas passing through the gas outlets 121 is discharged through gas discharge holes 111 of a heating plate bottom surface 101. The gas passing through the gas discharge holes 111 then hits wings 211 and 212 of a diffusion guide 200, which is arranged at an angle of about 75 degrees, as illustrated in FIGS. 14 and 15, causing the gas to spread widely in a radial direction rather than vertically toward the substrate 300. Then, when the gas is guided to be indirectly injected onto the substrate 300, the temperature distribution on the heating plate bottom surface 101 at a position corresponding to the substrate 300 appears even, showing a low temperature distribution, as shown in FIG. 16. The closer the flow uniformity is to 1, the more favorable, and it can be seen that the flow uniformity is close to 1 at about 0.85. Therefore, according to the embodiment of FIG. 10, it can be confirmed from FIG. 16 that an excellent flow uniformity can be provided. Here, the flow uniformity may be calculated, for example, as 1 minus the sum of the deviations of the gas flow velocities of each column of gas discharge holes 111 divided by the average gas flow velocity of the corresponding column of gas discharge holes 111, but the invention is not limited thereto.

A diffusion guide of a substrate heat treatment device, according to another embodiment, will hereinafter be described.

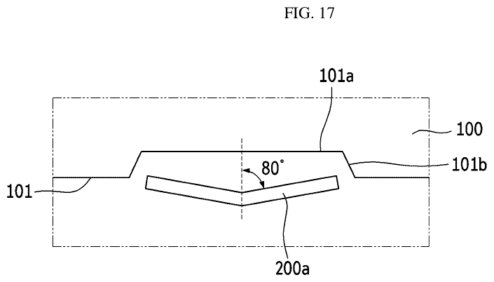

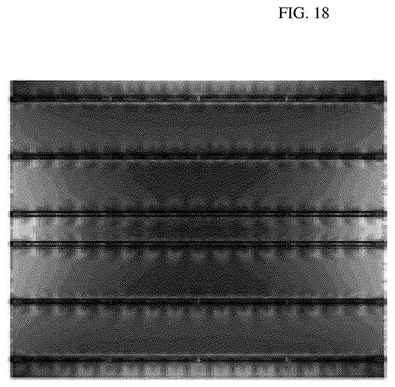

FIG. 17 is a partially enlarged cross-sectional view illustrating the state of a diffusion guide arranged at an angle of about 80 degrees on the bottom surface of a heating plate of FIG. 10, according to an embodiment, and FIG. 18 is a photograph showing the temperature simulation results for the heating plate bottom surface with the diffusion guide arranged at an angle of about 80 degrees according to the embodiment of FIG. 17.

The embodiment of FIG. 17 differs from the embodiment of FIG. 10 in that a diffusion guide 200a is arranged at an angle of about 80 degrees with respect to a reference line.

In an embodiment and referring to FIG. 17, when the diffusion guide 200a is arranged at an angle of about 80 degrees, the temperature distribution on a heating plate bottom surface 101 at a position corresponding to a substrate 300 appears even, showing a low temperature distribution, as shown in FIG. 18. The closer the flow uniformity is to 1, the more favorable, and it can be seen that the flow uniformity is excellent at about 0.85.

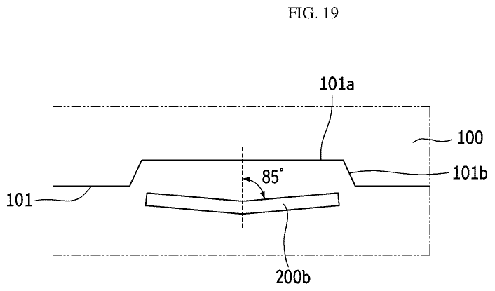

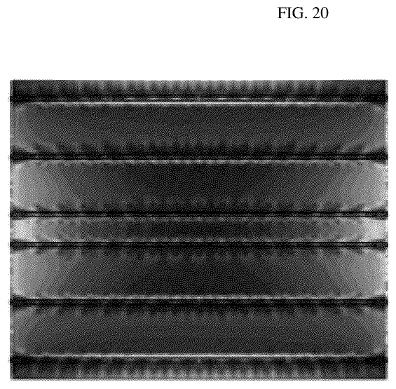

FIG. 19 is a partially enlarged cross-sectional view illustrating the state of a diffusion guide arranged at an angle of about 85 degrees on the bottom surface of the heating plate of FIG. 10, and FIG. 20 is a photograph showing the temperature simulation results for the heating plate bottom surface with the diffusion guide arranged at an angle of about 85 degrees according to the embodiment of FIG. 19.

The embodiment of FIG. 19 is the same as the embodiment of FIG. 10 except that a diffusion guide 200b is arranged at an angle of about 85 degrees with respect to a reference line.

In an embodiment and referring to FIG. 19, when the diffusion guide 200b is arranged at an angle of about 85 degrees, the temperature distribution on the heating plate bottom surface 101 appears even, except in the yellow areas at both ends, showing a low temperature distribution, as shown in FIG. 20. The closer the flow uniformity is to 1, the more favorable, and it can be seen that the flow uniformity is excellent at about 0.84.

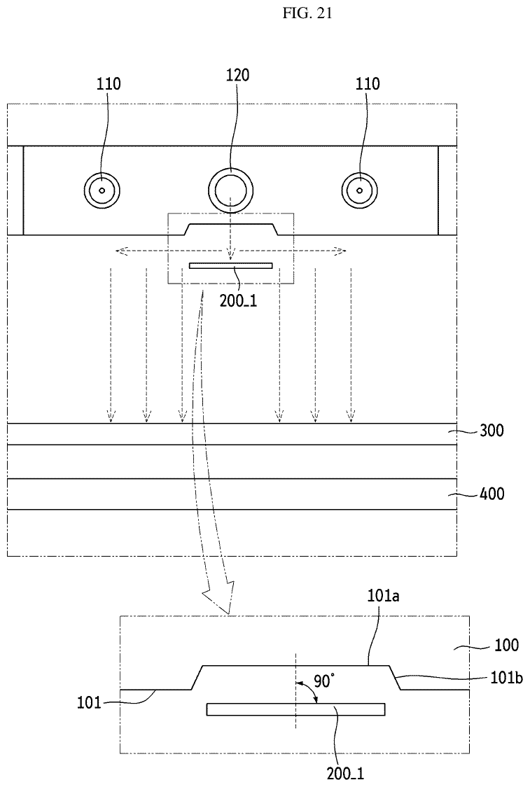

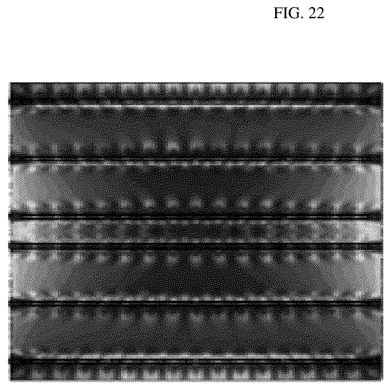

FIG. 21 is a view showing the state of a diffusion guide arranged at an angle of about 90 degrees on the bottom surface of the heating plate, according to the embodiment of FIG. 10, and FIG. 22 is a photograph showing the temperature simulation results for the heating plate bottom surface with the diffusion guide arranged at an angle of about 90 degrees according to the embodiment of FIG. 21.

The embodiment of FIG. 21 differs from the embodiment of FIG. 10 in that a diffusion guide 200_1 is arranged at an angle of about 90 degrees with respect to a reference line.

In an embodiment and referring to FIG. 21, when the diffusion guide 200_1 is arranged at an angle of about 90 degrees, the temperature distribution on the heating plate bottom surface 101 at a position corresponding to the substrate 300 appears overall yellow, indicating a high and non-uniform temperature distribution, as shown in FIG. 22. The closer the flow uniformity is to 1, the more favorable, but with a flow uniformity of about 0.83, it can be confirmed that the flow is not uniform. Additionally, the gas from a gas supply pipe 120 hits the substrate 300 directly, and the gas sprayed vertically does not spread widely but is concentrated in a certain area, causing stains on the substrate 300.

Thus, when the arrangement angle of a diffusion guide 200 is between about 70 degrees and about 89 degrees, the airflow of the gas emitted from a gas supply pipe 120 can be altered, and a space can be formed between the diffusion guide 200 and a heating plate bottom surface 101, thereby improving the uniformity of the gas flow passing through the diffusion guide 200. Specifically, when the arrangement angle of the diffusion guide 200 is about 75 degrees, the internal space of the diffusion guide 200 can act as a common chamber, resulting in even more uniform gas flow through the diffusion guide 200.

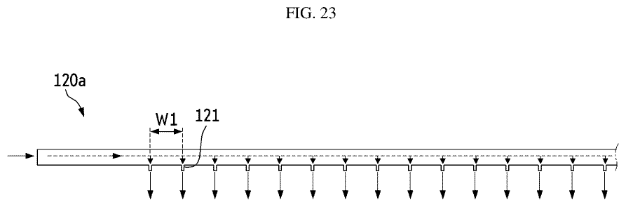

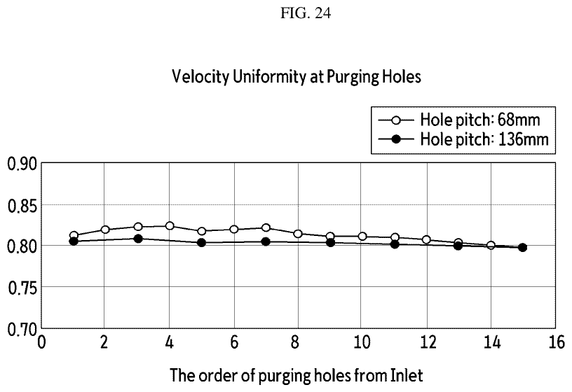

FIG. 23 is a cross-sectional view illustrating a gas supply pipe with a pitch of about 136 mm between gas outlets, according to the embodiment of FIG. 4, and FIG. 24 is a graph comparing the flow uniformity of the gas supply pipe with a pitch of about 68 mm in FIG. 6 and the gas supply pipe with a pitch of about 136 mm in FIG. 23.

The embodiment of FIG. 23 differs from the embodiment of FIG. 6 in that the pitch (or a spacing W1) between gas outlets 121 of a gas supply pipe 120a is about 136 mm.

Referring to FIG. 24, comparing the embodiments of FIG. 6 and FIG. 23, it can be confirmed that when the spacing W between the gas outlets 121 is about 68 mm, as illustrated in FIG. 6, the internal pressure of the gas supply pipe 120 decreases and the flow speed of the gas discharged through the gas outlets 121 is uniform. Specifically, in the embodiment of FIG. 6, unlike in the embodiment of FIG. 23 where the spacing W1 is about 136 mm, the speed uniformity of the gas discharged through the gas outlets 121 also increases. This shows that if purging holes such as the gas outlets 121 of FIG. 6 are formed with a narrow spacing, the flow uniformity can be improved.

Thus, the substrate heat treatment device 1 can guide gas toward each heating plate bottom surface 101 so as not to directly hit each substrate 300. Also, as gas outlets 121 can be formed with a smaller pitch therebetween, the internal airflow speed uniformity can be improved.

In concluding the detailed description, those skilled in the art will appreciate that many variations and modifications can be made to the invention without substantially departing from the principles and scope of the invention. Therefore, the disclosed embodiments are used in a generic and descriptive sense only and not for purposes of limitation. It will be understood by one of ordinary skill in the art to which the invention belongs that the invention may be implemented in other specific embodiments than those described herein without changing the technical spirit or essential features of the invention. Therefore, it is to be understood that the exemplary embodiments described above are illustrative rather than being restrictive in all aspects. The disclosed embodiments of the invention are used in a generic and descriptive sense only and not for purposes of limitation. Each component specifically shown in the embodiments of the invention can be implemented by modification, and such modifications and differences related to invention should be construed as being included in the scope of the invention. Moreover, the embodiments or parts of the embodiments may be combined in whole or in part without departing from the scope of the invention.

What is claimed is:

1. A substrate heat treatment device comprising:
a heat treatment chamber having a heat treatment space;
a gas injection unit located inside the heat treatment chamber and having a gas outlet configured to inject gas into the heat treatment chamber; and
a diffusion guide positioned adjacent to the gas injection unit within the heat treatment chamber, wherein the diffusion guide extends along a first horizontal direction intersecting a discharge direction of the gas emitted through the gas outlet,
wherein an inner surface of the diffusion guide facing the gas outlet includes a concave surface formed along a second horizontal direction intersecting the first horizontal direction.

2. The substrate heat treatment device of claim 1, wherein the diffusion guide includes a central line, a first wing located on one side of the central line and directed in the second horizontal direction, and a second wing located on the other side of the central line and directed in the second horizontal direction.

3. The substrate heat treatment device of claim 2, wherein the central line overlaps the gas outlet.

4. The substrate heat treatment device of claim 3, wherein the first wing and the second wing have symmetrical shapes with respect to the central line.

5. The substrate heat treatment device of claim 2, wherein each of the first wing and the second wing are closer to the gas injection unit as the first wing and the second wing extend away from the central line.

6. The substrate heat treatment device of claim 5, wherein each of the first wing and the second wing are spaced apart from the gas injection unit.

7. The substrate heat treatment device of claim 6, wherein a spacing disposed between the first wing and the gas injection unit and a spacing disposed between the second wing and the gas injection unit constitute a gas discharge space.

8. The substrate heat treatment device of claim 7, wherein the gas discharge space has a slit shape extending in the first horizontal direction.

9. The substrate heat treatment device of claim 2, wherein angles formed by the first wing and the second wing with respect to a vertical direction directed perpendicular to the first and second horizontal directions are each between about 70 degrees and about 89 degrees.

10. The substrate heat treatment device of claim 1, wherein
the gas injection unit includes a plurality of gas outlets arranged along a longitudinal direction of the gas injection unit, and
the plurality of gas outlets are spaced apart from one another at intervals of about 60mm to about 75 mm.

11. The substrate heat treatment device of claim 7, further comprising:
a heating unit located inside the heat treatment chamber, and including a gas discharge hole connected to the gas outlet,
wherein the gas injection unit is coupled to the heating unit at a position where the gas outlet and the gas discharge hole are connected.

12. The substrate heat treatment device of claim 11, wherein
the heating unit is arranged continuously along the first horizontal direction,
the heating unit includes a heating plate including the gas discharge hole and a heat pipe coupled to the heating plate, and
the gas injection unit includes a gas supply pipe coupled to the heating plate while being spaced apart from the heat pipe and overlapping the gas discharge hole.

13. The substrate heat treatment device of claim 12, wherein the diffusion guide is spaced apart from the heating plate with the gas discharge space disposed therebetween.

14. The substrate heat treatment device of claim 12, wherein the diffusion guide includes a block shape arranged continuously along a longitudinal direction of the heating plate.

15. The substrate heat treatment device of claim 12, further comprising:
a substrate support located inside the heat treatment chamber and positioned to face the heating unit to support a substrate to be heat-treated.

16. The substrate heat treatment device of claim 1, further comprising:
a gas supply unit connected to the gas injection unit to supply gas to the gas injection unit, and
a gas discharge unit for discharging the gas supplied into the heat treatment chamber to the outside of the heat treatment chamber.

17. A substrate heat treatment device comprising:
a heat treatment chamber defining a heat treatment space;
a gas injection unit located inside the heat treatment chamber and including a gas outlet configured to inject gas into the heat treatment chamber; and
a diffusion plate positioned adjacent to the gas injection unit within the heat treatment chamber, and located in a first horizontal direction intersecting a discharge direction of the gas emitted through the gas outlet,
wherein the diffusion plate includes a guide surface configured to move the gas in a direction opposite to the discharge direction.

18. The substrate heat treatment device of claim 17, wherein
the diffusion plate includes a bent portion located in a central region and a pair of inclined portions extending symmetrically in both directions from the bent portion, wherein
each of the pair of inclined portions include the guide surface.

19. The substrate heat treatment device of claim 18, wherein the pair of inclined portions each have an inclination angle of about 70 degrees to about 89 degrees with respect to a straight line directed in the discharge direction.

20. The substrate heat treatment device of claim 17, wherein
the gas injection unit includes a plurality of gas outlets arranged along a longitudinal direction of the gas injection unit, wherein
the plurality of gas outlets are spaced apart from one another at intervals of about 60 mm to about 75 mm.
